(19) United States
(12) Patent Application Publication
(10) Pub. No.: US 2003/0219540 A1
(43) Pub. Date: Nov. 27, 2003

(54) Pre-polycoating of glass substrates

(76) Inventors: Kam S. Law, Union City, CA (US); Dan Maydan, Los Altos Hills, CA (US)

Correspondence Address: APPLIED MATERIALS, INC., Patent Counsel, P.O. Box 450A, Santa Clara, CA, 95052, US

(21) Appl. No.: 10/386,371

(22) Filed: Mar. 11, 2003

Related U.S. Application Data
(63) Continuation of application No. 09/649,724, filed on Aug. 28, 2000, now abandoned.

(51) Int. Cl. C23C 16/00; B05D 3/02

(52) U.S. Cl. 427/376.2; 427/314; 427/255.28; 427/574

(57) ABSTRACT

A method and apparatus for forming a polysilicon layer on a pre-annealed glass substrate. In one aspect, the method includes loading a pre-annealed glass substrate in a deposition chamber, depositing an amorphous silicon layer on the pre-annealed glass substrate, and annealing the pre-annealed glass substrate to form a polysilicon layer thereon. The amorphous silicon layer may be deposited concurrently with the annealing step to produce the polysilicon layer on the pre-annealed glass substrate. A nitride layer and/or an oxide layer may be deposited prior to depositing the amorphous silicon layer and annealing the pre-annealed glass substrate.

### BACKGROUND OF THE INVENTION

1. Field of the Invention

The invention relates to a method and apparatus for use in processing substrates and forming films on glass substrates.

2. Background of the Related Art

Flat panel displays are replacing cathode-ray tube displays as the dominant medium in electronic display technology. Generally, flat panel display devices respond to a video signal to form an image on a screen. Such devices are used in conjunction with a host device which generates the image signal. Exemplary host devices include pocket televisions, notebook sized portable computers, calculators, telephones, or other appliances, particularly hand-held devices. One large commercial use for the flat panel display is to serve as a computer display, such as high resolution mono-chrome or color displays, in place of a large and heavy cathode ray tube (CRT) displays. A flat panel display, such as a liquid crystal display (LCD) or a field emission display (FED), is relatively light weight and consumes less power compared to the cathode ray tube. Such characteristics are particularly desirable for portable computing device displays, where light weight and low power usage are important attributes.

A LCD generally includes a backplate substrate, a faceplate substrate and a liquid crystal material sealed therebetween. The liquid crystal is an oily substance that flows like a liquid, but has a crystalline order in the arrangement of its molecules. An electrical field is applied to thread-like or pneumatic liquid crystal molecules which respond by reorienting themselves along electric field lines. Such orientation of the molecules causes light to be transmitted or blocked. The backplate typically comprises a glass substrate on which are formed a horizontal scanning circuit, a vertical scanning circuit and a pixel region. For an active matrix LCD (AMLCD), the glass substrate can comprise a large integrated circuit having millions of thin-film transistor (TFT) switches. The TFT switches form the horizontal and vertical scanning circuits.

To fabricate the backplate, glass is formed into an extremely flat substrate. The glass substrate may then be purified of alkali metals, which might contaminate the transistors or the liquid crystal. A thin film layer of semiconductive material, such as polysilicon, is then deposited by a plasma process to form a random network of silicon on the glass. Finally, metal electrodes, insulators and other elements are formed by depositing multiple layers of conducting, semiconducting, and dielectric materials on the glass substrate, and selectively removing the layers to fabricate integrated circuits and define TFT switches.

The glass substrate is an essential component of the flat panel display, and therefore, the optical and mechanical properties of the glass substrate need to be controlled at every stage of the flat panel display fabrication process. For example, in manufacturing active matrix liquid crystal displays (AMLCD), polysilicon can be deposited at high temperatures, i.e., greater than about 600° C. The deposited film and substrate may then be annealed at even higher temperatures for extended periods of time to improve the crystallinity of the deposited film. The exposure of the glass substrate to high temperatures over an extended period of time can result in deformation of the glass substrate as the glass substrate undergoes thermal expansion.

For example, heating the glass substrate at sufficiently high temperatures, such as during some deposition processes, can result in uncontrollable thermal expansion of the glass substrate at the strain point of the glass substrate. The strain point of the glass substrate occurs at the temperature where cooling of the glass substrate can no longer reverse the deformation of the glass substrate from heat expansion. The uncontrollable thermal expansion of the glass substrate can result in a deformed substrate after cooling which can detrimentally affect the quality of fabricated flat panels and devices formed thereon. The strain points of many commercially available glass substrates used in flat panel display fabrication are typically at temperatures between about 500° C. and 700° C.

Another problem that rises with the deformation of glass under thermal expansion is an increase of thermal stresses in the glass substrate. Thermal stresses in the glass substrate can result in breakage of the glass or misalignment of features during subsequent device fabrication steps. Misalignment of the features during deposition and etching processes, such as misalignment of features during the manufacture of TFTs, can detrimentally affect the reliability of the structures produced and result in a less than desirable display panel.

One solution to reduce the effect of thermal expansion during the manufacturing process is to anneal the glass substrate to “compact” or “shrink” the glass prior to depositing materials, such as polysilicon, so that deformation during device fabrication is reduced and the mechanical properties of the substrate are stabilized. However, the compacting anneal step is time consuming and adds further processing steps in the fabrication process of the glass substrate.

For example, currently, polysilicon films are deposited on glass substrate for the manufacture of polysilicon based TFT's by first forming the glass substrate, annealing the glass substrate to compact the glass substrate, then depositing an amorphous silicon film on the glass substrate, and annealing the amorphous silicon film on the glass substrate to form a polysilicon film. Typically, the anneal process used to compact the glass substrate is performed by the manufacturer of the glass substrate prior to transfer of the substrate to the display panel manufacturer. Then, the display panel manufacturer deposits the amorphous silicon layer on the annealed substrate and then anneals the deposited layer to form the polysilicon layer. Additionally, the glass substrate is still subjected to high processing temperatures during the deposition and annealing of the amorphous silicon film which may still deform the glass substrate.

Therefore, there is a need for a method for producing glass substrates having a polysilicon film formed thereon, prior to or concurrently with annealing the glass substrate. Ideally, the process would allow for processing glass substrates at higher processing temperatures and at reduced processing times with fewer processing steps.

### SUMMARY OF THE INVENTION

The invention generally provides a method for forming a polysilicon layer on a glass substrate by depositing an amorphous silicon layer before or during substrate annealing. In one aspect, a method is provided for processing a substrate comprising loading a pre-annealed glass substrate in a deposition chamber, depositing an amorphous silicon layer on the pre-annealed glass substrate, and annealing the pre-annealed glass substrate in the deposition chamber or in an annealing chamber to form a polysilicon layer thereon. Annealing the pre-annealed glass substrate may comprise annealing the pre-annealed glass substrate at a first substrate temperature and then annealing the glass substrate at a second temperature higher than the first temperature

In another aspect, a method is provided for processing a substrate, comprising loading a pre-annealed glass substrate in a deposition chamber and annealing the pre-annealed glass substrate while depositing an amorphous silicon layer on the pre-annealed glass substrate to form a polysilicon layer thereon. Annealing the pre-annealed glass substrate while depositing an amorphous silicon layer on the pre-annealed glass substrate may comprise depositing the amorphous silicon layer at a first temperature in the deposition chamber and then annealing the pre-annealed glass substrate at a second temperature higher than the first temperature in the deposition chamber or in an annealing chamber.

In another aspect, a method is provided for processing a substrate, comprising loading a pre-annealed glass substrate in an integrated platform, depositing a silicon nitride layer on the pre-annealed glass substrate, depositing a silicon oxide layer on the silicon nitride layer, depositing an amorphous silicon layer on the silicon oxide layer, and annealing the pre-annealed glass substrate to form a polysilicon layer thereon. The glass substrate may be annealed while depositing the amorphous silicon layer on the pre-annealed glass substrate to form a polysilicon layer thereon.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic cross-sectional view of an chemical vapor deposition chamber suitable for plasma enhanced deposition of a film;

FIG. 2 is a flow chart illustrating steps in forming the polysilicon layer on a glass substrate according to a first embodiment of the invention;

FIG. 3 is a flow chart illustrating steps in forming the polysilicon layer on a glass substrate according to a second embodiment of the invention;

FIG. 4 is a flow chart illustrating steps in forming the polysilicon layer on a glass substrate according to a third embodiment of the invention.

### DETAILED DESCRIPTION OF THE PREFERRED EMBODIMENT

The invention will be described below in reference to a chemical vapor deposition (CVD) process that can be carried out using process equipment, such as a Centura® platform, available from Applied Komatsu Technology, Inc., located in Santa Clara, Calif. The equipment preferably includes an integrated platform having a chemical vapor deposition (CVD) chamber, such as a plasma enhanced CVD (PECVD) chamber commercially available from Applied Komatsu Technology, Inc., of Santa Clara, Calif. Any chamber enabling the deposition of amorphous silicon material on a substrate can be used to advantage, such as, for example, a high density plasma chemical vapor deposition (HDP-CVD) chamber. The following CVD chamber description is illustrative and should not be interpreted or construed as limiting the scope of the invention.

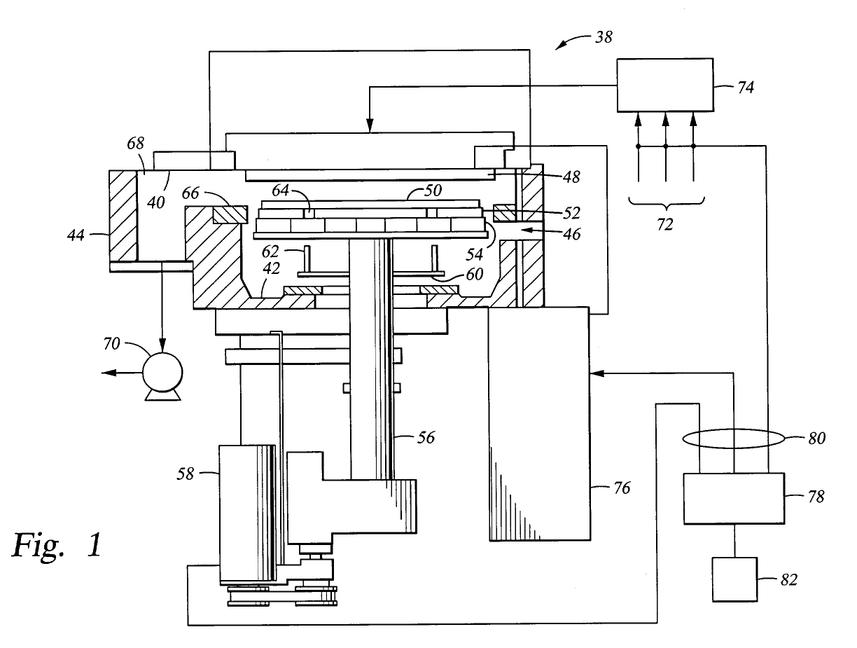

FIG. 1 is a schematic cross-sectional view of an chemical vapor deposition chamber 38 suitable for depositing an amorphous silicon film by a thermal or plasma enhanced process for processing flat panel displays. The chamber 38 is a parallel plate CVD chamber having a top 40, bottom 42, sidewalls 44 and an opening 46 disposed in the sidewall through which substrates are delivered and retrieved from the chamber. Chamber 38 contains a gas distribution manifold 48, known as a diffuser, for dispersing process gases through perforated holes in the manifold to a substrate 50 that rests on a susceptor 52.

Susceptor 52 is mounted on a support frame 54 and the support frame 54 is mounted on a support stem 56. The susceptor 52 is typically a plate of aluminum and is heated by a resistive heater (not shown) embedded in the susceptor 52. The heater provides rapid and uniform susceptor and substrate heating during deposition. The susceptor 52 and the substrate 50 supported on the susceptor 52 can be controllably moved by a lift motor 58, such as a Z-drive, to adjust the spacing between the manifold 48 and the substrate 50. The spacing typically ranges between about 200 mils to about 1000 mils. The susceptor 52 is movable between a lower loading/off-loading position and an upper processing position that is closely adjacent to the manifold 48. A lift plate 60 having lift pins 62 is disposed below the support frame 54.

When the support frame 54 is lowered, the lift pins 62 protrude through spaces in the support frame 54 and through holes 64 in the susceptor 52 to lift the substrate 50 from the susceptor and facilitate delivery and retrieval of the substrate 50 to and from the chamber 38. Alternatively, holes can be provided in one or more of the members of the support frame to allow the lift pins 62 to protrude through the members and through the susceptor to lift the substrate from the susceptor. An insulator 66 surrounds the susceptor 52 and the substrate 50.

Deposition and carrier gases are input through gas supply lines 72 into a mixing system 74 where they are combined and then sent to manifold 48. Alternatively, the mixing system 74 may be omitted and the gases flown to the manifold 48 directly. Generally, the process gas supply lines 72 for each of the process gases include i) safety shut-off valves (not shown) that can be used to automatically or manually shut off the flow of process gas into the chamber, particularly when toxic gases are used in the process, and ii) mass flow controllers (also not shown) that measure the flow of gas through the gas supply lines.

During processing, gases flown to manifold 48 are uniformly distributed across the surface of the substrate. The gases exhaust through a port 68 by a vacuum system 70 having a throttle valve (not shown) to control the pressure in the chamber 38 by controlling the exhaust rate of gas from the chamber 38.

The deposition process performed in chamber 38 can be any process, such as a thermal process or a plasma-enhanced process. In a plasma-enhanced process, a controlled plasma is formed adjacent to the substrate by RF energy applied to gas distribution manifold 48, or another plasma energizing device or structure, from an RF power supply 76. The susceptor 52 is grounded and the manifold 48 is electrically isolated from the chamber surfaces. The plasma creates a reaction zone between the gas distributor manifold 48 and the substrate 50 that enhances the reaction between the process gases.

RF power supply 76 can provide either single or mixed frequency RF power to manifold 48 to enhance the decomposition of reactive species introduced into chamber 38. A mixed frequency RF power supply typically provides power at a high RF frequency (RF1) of about 13.56 MHz and at a low RF frequency (RF2) of about 350 kHz.

Typically, any or all of the chamber linings, gas distribution manifold 48, support stem 56, and various other chamber hardware are made of material such as aluminum or aluminum oxide. An example of such a CVD chamber is described in U.S. Pat. No. 5,000,113, entitled “Thermal CVD/PECVD Chamber and Use for Thermal Chemical Vapor Deposition of Silicon Dioxide and In-situ Multi-step Planarized Process,” issued to Wang et al., and assigned to Applied Materials, Inc., the assignee of the present invention.

The lift motor 58, the gas mixing system 74, and the RF power supply 76 are controlled by a system controller 78 over control lines 80. The chamber includes analog assemblies such as mass flow controllers (MFCs), RF generators, and lamp magnet drivers that are controlled by the system controller 78 which executes system control software stored in a memory 82. Motors and optical sensors are used to move and determine the position of movable mechanical assemblies such as the throttle valve of the vacuum system 70 and lift motor 58 for positioning the susceptor 52.

The system controller 78 controls all of the activities of the CVD chamber and preferably includes a hard disk drive, a floppy disk drive, and a card rack. The card rack contains a single board computer (SBC), analog and digital input/output boards, interface boards and stepper motor controller boards. The system controller preferably conforms to the Versa Modular Europeans (VME) standard that defines board, card cage, and connector dimensions and types.

### The Deposition Processes

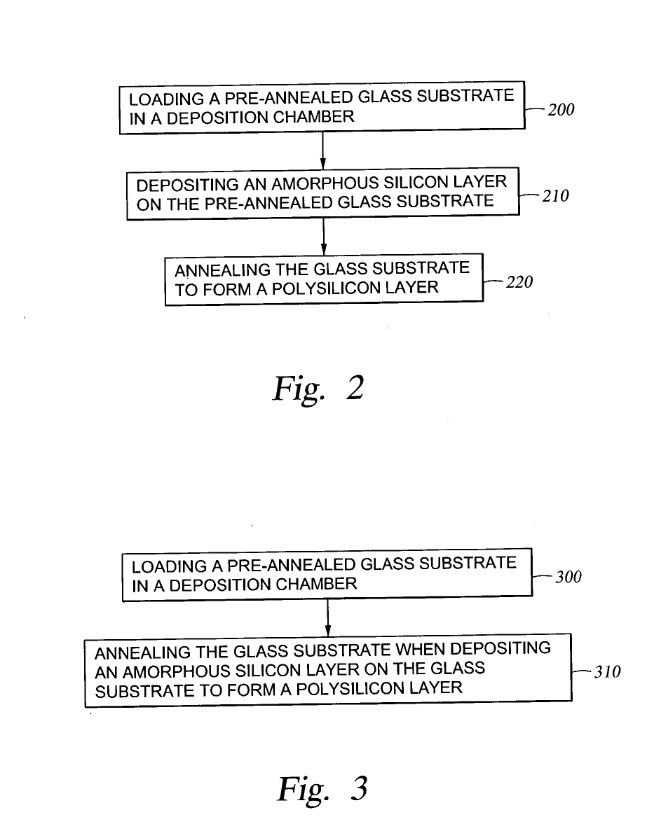

FIG. 2 is a flow chart of one embodiment of a sequential deposition process to form a polysilicon film on a glass substrate. The process begins by loading a pre-annealed glass substrate in a deposition chamber at step 200. A pre-annealed glass substrate is broadly defined herein as a glass substrate prior processing at a temperature of about 350° C. or greater. Glass substrates with precise dimensions and reproducible mechanical properties are made, for example, by a fusion process or a float process.

The glass substrate may comprise silica glass, soda-lime glass, borosilicate glass, sodium borosilicate glass, alkali-metal borosilicate, aluminosilicate glass, aluminoborosilicate glass, alkaline earth aluminoborosilicate glass, alkaline earth-metal aluminoborosilicate glass, and combinations thereof. Typically, a glass substrate with preferred glass properties or compositions are selected for forming particular semiconductor devices. For example, a special formulation of alkaline earth glass, such as alkaline earth-metal aluminosilicate glass, is used for AMLCD displays to minimize doping or contamination of alkali metals or boron in transistors formed in a polysilicon film. The presence of alkali or boron contaminants may degrade transistor performance. However, the above list is illustrative and it is contemplated that the glass substrate may comprise other commercially available glasses and dopant materials known in the art for producing flat panel displays.

The pre-annealed glass substrate is then processed by depositing an amorphous silicon layer on the glass substrate at step 210. The amorphous silicon film is deposited on the glass substrate in a deposition chamber after the glass substrate is formed prior to or while annealing of the glass substrate. Preferably, this is performed prior to any anneal process performed on the substrate. The amorphous silicon layer is deposited by a plasma-enhanced deposition process in the chemical vapor deposition chamber 38 described above.

The amorphous silicon layer is deposited by introducing a silane gas, or derivative thereof, such as disilane, at a flow rate between about 100 sccm and about 1500 sccm into the processing chamber. The flow rate of silane is dependent on the size of the chamber and substrate being processed. For example, a silane flow rate between about 140 and about 200 sccm is used for 400 mm by 500 mm substrates, while a silane flow rate between about 300 and about 500 sccm is used for depositing amorphous silicon films on 600 mm by 720 mm substrates. Optionally, hydrogen may be introduced into the processing chamber at a flow rate between about 500 sccm and about 4000 sccm to enhance the deposition of the amorphous silicon film. A plasma is generated by supplying a power at a level between about 50 watts and about 5000 watts to the processing chamber. A power level between about 300 watts and about 2000 watts is preferably supplied to deposit the amorphous silicon film.

During the deposition process, the chamber is maintained at a pressure between about 100 milliTorr and about 15 Torr. Preferably, a chamber pressure between about 500 milliTorr and about 5 Torr is used. The substrate is maintained at a temperature between about 200° C. and about 650° C. during the deposition process. Preferably, the substrate is maintained at a temperature between about 250° C. and about 450° C. Most preferably, the substrate temperature is maintained between about 300° C. and about 450° C. The showerhead is generally spaced from the substrate by a distance between about 400 mils (thousandth of an inch) and about 1500 mils, or between about 10 mm and about 37.5 mm.

In an exemplary deposition process, the amorphous silicon film is deposited on a pre-annealed glass substrate by introducing silane at a flow rate between about 140 and about 200 sccm into a processing chamber, maintaining a chamber pressure of about 1.3 Torr, maintaining the substrate at a temperature of about 320° C., positioning the showerhead at about 960 mils from the substrate, and generating a plasma by supplying a power between about 100 and about 200 watts to a gas distribution manifold to deposit a film on the substrate.

It is contemplated that the amorphous silicon layer can be deposited by other methods known in the art such as by sub-atmospheric chemical vapor deposition (SACVD) or high density plasma chemical vapor deposition (HDP-CVD). A high density chemical vapor deposition process for amorphous silicon films is more fully described in co-pending U.S. patent application Ser. No. 60/216,865, entitled “Deposition Of Amorphous Silicon Films By High Density Plasma HDP-CVD At Low Temperatures,” filed on Jul. 7, 2000, which application is incorporated herein by reference to the extent not inconsistent with the invention.

A polysilicon layer is then formed on the glass substrate by annealing the amorphous silicon film on the glass substrate in the amorphous silicon deposition chamber or in an annealing chamber. The glass substrate is preferably annealed in a two-step process to produce the polysilicon layer. The glass substrate is annealed at an initial temperature between about 400° C. and about 500° C. for about 5 minutes to about 2 hours, with longer annealing times at lower temperatures. For example, an amorphous silicon film of less than about 500 Å is annealed for about 10 minutes at about 450° C. Annealing at the initial temperature allows the removal of hydrogen from the amorphous silicon films, often referred to as dehydrogenation, prior to a crystallization or recrystallization process.

The amorphous silicon film is annealed at a second temperature higher than the first temperature by heating the substrate to a temperature between about 500° C. and about 900° C. for between about 30 minutes and about 18 hours. Generally, for a glass substrate, the annealing temperature is between about 500° C. and about 650° C. for between about 30 minutes and about 2 hours. For example, an amorphous silicon film of less than about 500 Å deposited on a pre-annealed glass substrate is annealed for about 2 hours at about 600° C. The second anneal process is used to crystallize or recrystallize the amorphous silicon film to form a polysilicon film. Preferably, the two steps of the annealing process are performed in situ by annealing at the first temperature to at least partially dehydrogenate the film and then annealing at the second temperature to crystallize the amorphous film to produce the polycrystalline film.

The annealing of the substrate at the initial temperature or the second temperature is preferably performed in an annealing furnace, but all or part of the annealing processes may be performed by other processes and apparatus known in the art, such as by a laser annealing process or in a processing chamber capable of heating the substrate to the required temperature. For example, the initial annealing step is performed in situ in the PECVD processing chamber used to deposit the amorphous silicon film. Alternatively, the annealing process is performed in a rapid thermal anneal chamber, such as a RTP XEplus Centura® thermal processor, commercially available from Applied Material, of Santa Clara, Calif. Other anneal processes known in the art that can be performed before or concurrently with the amorphous silicon deposition process may be used.

It is believed by depositing an amorphous silicon film prior to annealing the glass substrate, a polysilicon film can be formed on the substrate while reducing thermal stresses, controlling glass substrate deformation, and compacting the glass substrate for further processing. Further, it is believed by depositing the amorphous silicon film prior to annealing, the process steps, and thus, the processing times to form flat panels can be reduced over the prior art.

Referring to FIG. 3, a second embodiment of the invention provides for annealing the glass substrate and amorphous silicon film in the deposition chamber during the deposition of the amorphous silicon film to produce the polysilicon film. In this process, the pre-annealed glass substrate is first loaded at step 300 as described above and then transferred to the CVD processing chamber 38 for deposition of the amorphous silicon layer at step 310. The amorphous silicon layer is then deposited at a sufficient temperature to anneal the glass substrate to produce a polysilicon film.

One exemplary processing regime comprises introducing silane at a flow rate between about between about 100 sccm and about 1500 sccm, maintaining the chamber at a pressure between about 100 milliTorr and about 15 Torr, generating a plasma at a power between about 50 watts and about 5000 watts, and maintaining the substrate temperature at a temperature between about 350° C. and about 650° C., thereby annealing the amorphous silicon film and glass substrate to form a polysilicon film. Optionally, hydrogen may be introduced into the processing chamber at a flow rate of between about 500 sccm and about 4000 sccm to enhance deposition of the amorphous silicon film.

The amorphous silicon film and glass substrate may be annealed in a two-step process by depositing a amorphous silicon film at a first temperature between about 400° C. and about 550° C. which can anneal and dehydrogenate the amorphous silicon film during deposition and then further annealing the amorphous silicon film and glass substrate in situ at a second temperature between about 500° C. and about 650° C. to crystallize or recrystallize the amorphous silicon film to produce the polysilicon film.

The polysilicon film, for example, may also be formed while annealing the glass substrate by depositing the silicon film at temperatures of greater than about 450° C. in an atmospheric pressure chemical vapor deposition (APCVD) or low pressure chemical vapor deposition (LPCVD) technique using a silane precursor. An example of a suitable LPCVD process is disclosed in U.S. Pat. No. 5,607,724, entitled “Low Temperature High Pressure Silicon Deposition Method,” issued on Mar. 4, 1997, assigned to common assignee, and incorporated by reference to the extent not inconsistent with the invention.

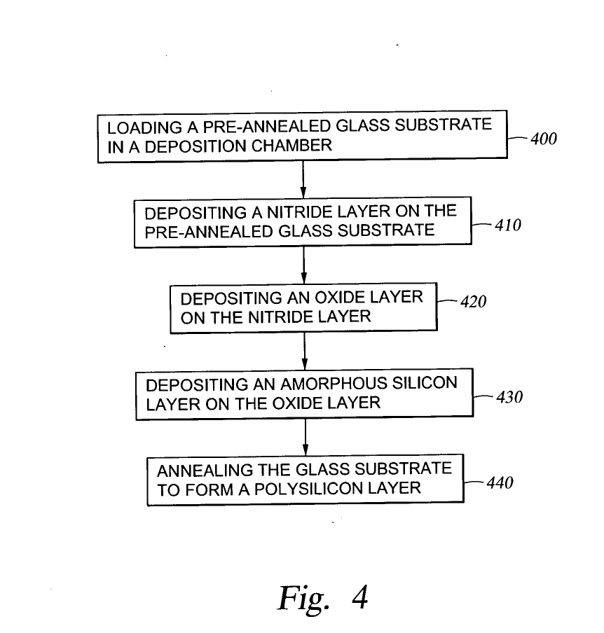

FIG. 4 is a flow diagram of a third embodiment of the invention for processing a substrate to produce a polysilicon film. The process is initiated by loading a pre-annealed glass substrate in a deposition chamber at step 400, and then depositing a silicon nitride layer on the glass substrate at step 410. An silicon oxide layer is then deposited on the silicon nitride layer at step 420. Next, an amorphous silicon layer is deposited on the silicon oxide layer at step 430. The substrate is then annealed to form the polysilicon layer at step 440. Alternatively, the glass substrate may be annealed while depositing the amorphous silicon layer on the glass substrate to form a polysilicon layer thereon.

A silicon nitride film is then deposited on the pre-annealed glass substrate at step 410. The silicon nitride film acts as a barrier to migration of alkali atoms, such as sodium used in forming some glass substrates, which may diffuse at high temperatures into subsequently deposited materials such as polysilicon. It is also believed that the silicon nitride layer improves interlayer adhesion between the glass substrate and the deposited amorphous silicon film. The silicon nitride film is deposited by a plasma-enhanced chemical vapor deposition process and may be performed using the CVD chamber described above.

The silicon nitride layer is deposited by introducing a silane gas at a flow rate between about 100 sccm and about 500 sccm, introducing ammonia at a flow rate between about 500 sccm and about 4000 sccm, introducing nitrogen gas at a flow rate between about 1000 sccm and about 20,000 sccm into the processing chamber, and generating a plasma by supplying a power level between about 500 watts and about 4000 watts to the processing chamber to deposit the silicon nitride film.

During the deposition process, the processing chamber is maintained at a pressure of about 0.5 Torr or greater and the substrate is maintained at a temperature of about 450° C. or below. The processing chamber is preferably maintained at a pressure between about 0.8 Torr and about 2.0 Torr. The substrate is preferably maintained at a temperature between about 300° C. and about 450° C. The showerhead is generally spaced from the substrate by a distance between about 700 mils and about 1500 mils (thousandths of an inch), or a distance between about 17 mm and about 38 mm. Preferably, the showerhead is spaced at a distance between about 1000 mils and about 1200 mils, or a distance between about 25 mm and about 30 mm. The deposition of the silicon nitride film is more fully described in U.S. Pat. No. 5,399,387, entitled “Plasma CVD of Silicon Nitride Thin Films on Large Area Glass Substrates at High Deposition Temperatures,” issued on Mar. 21, 1995, assigned to common assignee, and incorporated by reference to the extent not inconsistent with the invention.

A silicon dioxide layer is then deposited on the silicon nitride layer at step 420. The silicon dioxide layer is deposited on the substrate to act as an underlayer between the glass substrate and the polysilicon layer. The silicon dioxide prevents diffusion of chemical contaminants, such as sodium, from the glass substrate into the polysilicon layer as well as performing as an electrically insulating layer for polysilicon films in thin-film-transistor (TFT) fabrication.

An exemplary processing regime for depositing a silicon dioxide film is as follows. The silicon dioxide layer is deposited by introducing a silane gas at a flow rate between about 20 sccm and about 400 sccm, introducing nitrous oxide at a flow rate between about 4000 sccm and about 15,000 sccm into the processing chamber, and generating a plasma by supplying a power level between about 500 watts and about 3000 watts to the processing chamber to deposit the silicon nitride film.

During the deposition process, the processing chamber is maintained at a pressure of about 0.8 Torr or greater, and the substrate is maintained at a temperature of about 450° C. or below. The processing chamber is preferably maintained at a pressure between about 0.8 Torr and about 2.0 Torr. The substrate is preferably maintained at a temperature between about 300° C. and about 450° C. The showerhead is generally spaced from the substrate by a distance between about 700 mils and about 1500 mils (thousandths of an inch), or a distance between about 17 mm and about 38 mm. The deposition of the silicon nitride film is more fully described in U.S. Pat. No. 5,851,602, entitled “Deposition of High Quality Conformal Silicon Oxide Thin Films for The Manufacture of Thin Film Transistors,” issued on Dec. 22, 1998, assigned to common assignee, and incorporated by reference to the extent not inconsistent with the invention. The silicon oxide layer may be deposited in situ with the silicon nitride layer in the CVD chamber described above.

An amorphous silicon layer is then deposited on the silicon oxide layer at step 430 by the amorphous silicon deposition process described herein. The amorphous silicon layer may be deposited in situ with the silicon nitride layer and/or silicon oxide layer in the CVD chamber described above.

In one exemplary deposition regime, the amorphous silicon film is deposited by introducing silane at a flow rate between about 100 sccm and about 1500 sccm into a processing chamber, maintaining a chamber pressure of about 1.3 Torr, maintaining the substrate at a temperature of about 320° C., positioning the showerhead at about 960 mils from the substrate, and generating a plasma by supplying a power level of about 700 watts to deposit a film on the substrate. Optionally, hydrogen may be introduced into the processing chamber at a flow rate of between about 500 sccm and about 4000 sccm to enhance deposition of the amorphous silicon film.

The polysilicon layer is then formed on the glass substrate by annealing the amorphous silicon film on the glass substrate at step 440. The glass substrate is preferably annealed in a two-step process to produce the polysilicon layer. The two-step process comprises annealing the substrate at an initial temperature and then annealing the glass substrate at a second temperature higher than the first temperature.

The glass substrate is annealed at an initial temperature between about 400° C. and about 500° C. for about 5 minutes to about 2 hours, with longer annealing times at lower temperatures or for thicker films. The amorphous silicon film is annealed at an second temperature by heating the substrate to a temperature between about 500° C. and about 900° C. for between about 30 minutes and 18 hours. Generally, the anneal at the second temperature is between about 500° C. and about 650° C. for between 30 minutes and 18 hours. Preferably, the two step annealing steps are performed in situ by annealing at the first temperature to at least partially dehydrogenate the film and then annealing at the second temperature to crystallize the amorphous film to produce the polycrystalline film. The second annealing step may also be performed in situ within the same chamber as the deposition of the amorphous silicon film and the initial annealing step.

Alternatively, the glass substrate and amorphous silicon film may be annealed during the deposition of the amorphous silicon film to produce the polysilicon film. In this process, the amorphous silicon film is deposited under sufficient processing conditions to anneal the substrate under the above described temperatures. Further, the film may be deposited at a first temperature between about 400° C. and about 550° C. to dehydrogenate the amorphous silicon film being deposited and then annealed in situ at a second temperature between about 500° C. and about 650° C. to crystallize or recrystallize the amorphous silicon film to produce the polysilicon film.

While the foregoing is directed to the preferred embodiment of the present invention, other and further embodiments of the invention may be devised without departing from the basic scope thereof, and the scope thereof is determined by the claims that follow.

What is claimed is:

1. A method for processing a substrate, comprising:
(a) loading a pre-annealed glass substrate in a deposition chamber;
(b) depositing an amorphous silicon layer on the pre-annealed glass substrate; and
(c) annealing the pre-annealed glass substrate to form a polysilicon layer thereon.

2. The method of claim 1, wherein the pre-annealed glass substrate is annealed while depositing the amorphous silicon layer.

3. The method of claim 1, wherein the amorphous silicon layer is deposited by a plasma enhanced chemical vapor deposition technique.

4. The method of claim 1, wherein annealing the pre-annealed glass substrate comprises annealing the pre-annealed glass substrate at a first substrate temperature and then annealing the glass substrate at a second temperature higher than the first temperature.

5. The method of claim 4, wherein the first temperature is between about 400° C. and about 500° C.

6. The method of claim 5, wherein the pre-annealed glass substrate is annealed at the first temperature between about 5 minutes and about 2 hours.

7. The method of claim 4, wherein the second temperature is between about 500° C. and about 650° C.

8. The method of claim 7, wherein the glass substrate is annealed at a second temperature between about 30 minutes and about 18 hours.

9. The method of claim 1, wherein depositing the amorphous silicon layer and annealing the pre-annealed glass substrate are performed in the same deposition chamber.

10. A method for processing a substrate, comprising:
(a) loading a pre-annealed glass substrate in a deposition chamber; and
(b) annealing the pre-annealed glass substrate while depositing an amorphous silicon layer on the pre-annealed glass substrate to form a polysilicon layer thereon.

11. The method of claim 10, wherein the amorphous silicon layer is deposited by plasma enhanced chemical vapor deposition technique.

12. The method of claim 10, wherein the amorphous silicon layer is deposited at a substrate temperature between about 350° C. and about 650° C.

13. The method of claim 10, wherein annealing the pre-annealed glass substrate while depositing an amorphous silicon layer on the pre-annealed glass substrate comprises depositing the amorphous silicon layer at a first temperature and then annealing the glass substrate at a second temperature higher than the first temperature.

14. The method of claim 13, wherein the amorphous silicon layer is deposited at a first temperature between about 350° C. and about 500° C.

15. The method of claim 13, wherein the second temperature is between about 500° C. and about 650° C.

16. The method of claim 15, wherein the pre-annealed glass substrate is annealed at a second temperature between about 30 minutes and about 2 hours.

17. A method for processing a substrate, comprising:
(a) loading a pre-annealed glass substrate in an integrated platform;
(b) depositing a silicon nitride layer on the pre-annealed glass substrate;
(c) depositing a silicon oxide layer on the nitride layer;
(d) depositing an amorphous silicon layer on the oxide layer; and
(e) annealing the pre-annealed glass substrate to form a polysilicon layer thereon.

18. The method of claim 17, wherein the silicon nitride layer is deposited by plasma enhanced chemical vapor deposition technique.

19. The method of claim 17, wherein the silicon oxide layer comprises silicon dioxide and is deposited by plasma enhanced chemical vapor deposition technique.

20. The method of claim 17, wherein the silicon nitride layer and the silicon oxide layer are deposited sequentially in the same processing chamber.

21. The method of claim 17, wherein the amorphous silicon layer is deposited by plasma enhanced chemical vapor deposition technique.

22. The method of claim 17, wherein the silicon oxide layer and the amorphous silicon layer are deposited sequentially in the same processing chamber.

23. The method of claim 17, wherein the silicon nitride layer, the silicon oxide layer, and the amorphous silicon layer are deposited sequentially in the same processing chamber.

24. The method of claim 17, wherein annealing the pre-annealed glass substrate comprises annealing the pre-annealed glass substrate at a first substrate temperature and then annealing the glass substrate at a second temperature higher than the first temperature.

25. The method of claim 24, wherein the first temperature is between about 400° C. and about 500° C.

26. The method of claim 24, wherein the second temperature is between about 500° C. and about 650° C.

27. The method of claim 17, wherein depositing the amorphous silicon layer and annealing the pre-annealed glass substrate are performed in the same processing chamber.

28. The method of claim 17, wherein the pre-annealed glass substrate is annealed while depositing the amorphous silicon layer.
